(19) United States
(12) Patent Application Publication
(10) Pub. No.: US 2026/0276681 A1
(43) Pub. Date: Sep. 17, 2026

(54) TRANSIENT OVERVOLTAGE DETECTION SYSTEM AND METHOD

(71) Applicant: Siemens Energy Global GmbH & Co. KG, München (DE)

(72) Inventor: Seyed Amir Mahmood Najafi, Kirchheim unter Teck (DE)

(21) Appl. No.: 18/873,779

(22) PCT Filed: May 19, 2023
(86) PCT No.: PCT/US2023/067205

§ 371 Date: Dec. 11, 2024

Related U.S. Application Data
(60) Provisional application No. 63/351,512, filed on Jun. 13, 2022.

(51) Int. Cl. G01R 19/00; G01R 19/25

(52) U.S. Cl. CPC G01R 19/0053; G01R 19/2509; G01R 19/2513

(57) ABSTRACT

A detection system for detecting a transient overvoltage event in an electrical system that operates at a system frequency includes an analog circuit connected to the electrical system and having a high pass filter operable to allow for the passage of a transient voltage signal having a signal frequency greater than the system frequency. A digital circuit includes an analog to digital convertor that operates to convert the transient voltage signal to a digital transient voltage signal and a microprocessor operable to receive the digital transient voltage signal, to direct the digital transient voltage signal to a data storage device for storage in an overvoltage database, and to reset the analog circuit. A computer system is operable to output the data stored in the overvoltage database.

### BACKGROUND

Current overvoltage detection systems are expensive and can be too slow to catch all the various transients that may occur. Due to the cost of existing systems, some equipment is left unmonitored.

### SUMMARY

In one aspect, a detection system for detecting a transient overvoltage event in an electrical system that operates at a system frequency includes an analog circuit connected to the electrical system and having a high pass filter operable to allow for the passage of a transient voltage signal having a signal frequency greater than the system frequency. A digital circuit includes an analog to digital convertor that operates to convert the transient voltage signal to a digital transient voltage signal and a microprocessor operable to receive the digital transient voltage signal, to direct the digital transient voltage signal to a data storage device for storage in an overvoltage database, and to reset the analog circuit. A computer system is operable to output the data stored in the overvoltage database.

In another aspect, a detection system for detecting a transient overvoltage event in an electrical system that operates at a system frequency includes an analog circuit connected to the electrical system and having a high pass filter operable to allow for the passage of a transient voltage signal having a signal frequency greater than the system frequency, and a low pass filter operable to allow for the passage of a system voltage signal at the system frequency. The detection system also includes a digital circuit having an analog to digital convertor that operates to convert the transient voltage signal to a digital transient voltage signal and to convert the system voltage signal to a digital system voltage signal. A microprocessor is operable to receive the digital transient voltage signal and the digital system voltage signal and to compare the digital transient voltage signal and the digital system voltage signal to determine a phase angle of the system voltage signal when the transient voltage signal was generated. The microprocessor further operable to determine an overvoltage value, to direct the overvoltage value and the associated phase angle to a data storage device for storage in an overvoltage database, and to reset the analog circuit. The detection system also includes a computer system operable to output the data stored in the overvoltage database.

In another aspect, a method of detecting a transient overvoltage event in an electrical system that operates at a system frequency includes passing a signal from the electrical system to an analog circuit, filtering the signal to pass a first transient voltage signal having a signal frequency greater than the system frequency, and amplifying the first transient voltage signal. The method further includes converting the first transient voltage signal to a digital transient voltage signal in a digital circuit, determining an overvoltage value for the digital transient voltage signal, storing the overvoltage value for the digital transient voltage signal, and resetting the analog circuit to allow the analog circuit to detect a second transient voltage signal.

The foregoing has broadly outlined some of the technical features of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiments disclosed as a basis for modifying or designing other structures for carrying out the same purposes of the present disclosure. Those skilled in the art will also realize that such equivalent constructions do not depart from the spirit and scope of the disclosure in its broadest form.

Also, before undertaking the Detailed Description below, it should be understood that various definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

To easily identify the discussion of any particular element or act, the most significant digit or digits in a reference number refer to the figure number in which that element is first introduced.

FIG. 1 is a schematic illustration of an overvoltage detection system with a high pass filter.

FIG. 2 is a schematic illustration of another overvoltage detection system with a high pass filter and a low pass filter.

FIG. 3 is a flow chart illustrating operation of the overvoltage detection systems of FIG. 1 and FIG. 2.

FIG. 4 is an image of a graphical user interface that presents data collected by the overvoltage detection systems of FIG. 1 and FIG. 2.

FIG. 5 is an image of an overvoltage detection system icon for use with the graphical user interface of FIG. 4.

FIG. 6 is an image of another graphical user interface that displays data collected by the overvoltage detection system of FIG. 2.

### DETAILED DESCRIPTION

Before any embodiments of the invention are explained in detail, it is to be understood that the invention is not limited in its application to the details of construction and the arrangement of components set forth in this description or illustrated in the following drawings. The invention is capable of other embodiments and of being practiced or of being carried out in various ways. Also, it is to be understood that the phraseology and terminology used herein is for the purpose of description and should not be regarded as limiting.

Various technologies that pertain to systems and methods will now be described with reference to the drawings, where like reference numerals represent like elements throughout. The drawings discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged apparatus. It is to be understood that functionality that is described as being carried out by certain system elements may be performed by multiple elements. Similarly, for instance, an element may be configured to perform functionality that is described as being carried out by multiple elements. The numerous innovative teachings of the present application will be described with reference to exemplary non-limiting embodiments.

It should be understood that the words or phrases used herein should be construed broadly, unless expressly limited in some examples. For example, the terms “including,” “having,” and “comprising,” as well as derivatives thereof, mean inclusion without limitation. The singular forms “a”, “an” and “the” are intended to include the plural forms as well, unless the context clearly indicates otherwise. Further, the term “and/or” as used herein refers to and encompasses any and all possible combinations of one or more of the associated listed items. The term “or” is inclusive, meaning and/or, unless the context clearly indicates otherwise. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Furthermore, while multiple embodiments or constructions may be described herein, any features, methods, steps, components, etc. described with regard to one embodiment are equally applicable to other embodiments absent a specific statement to the contrary.

Also, although the terms “first”, “second”, “third” and so forth may be used herein to refer to various elements, information, functions, or acts, these elements, information, functions, or acts should not be limited by these terms. Rather these numeral adjectives are used to distinguish different elements, information, functions or acts from each other. For example, a first element, information, function, or act could be termed a second element, information, function, or act, and, similarly, a second element, information, function, or act could be termed a first element, information, function, or act, without departing from the scope of the present disclosure.

In addition, the term “adjacent to” may mean that an element is relatively near to but not in contact with a further element or that the element is in contact with the further portion unless the context clearly indicates otherwise. Further, the phrase “based on” is intended to mean “based, at least in part, on” unless explicitly stated otherwise. Terms “about” or “substantially” or like terms are intended to cover variations in a value that are within normal industry manufacturing tolerances for that dimension. If no industry standard is available, a variation of twenty percent would fall within the meaning of these terms unless otherwise stated.

Electrical systems such as power generation systems, grids, microgrids, and the like generate or use electricity that is provided at a system voltage and a system frequency. These systems are often positioned and arranged such that they are susceptible to disturbances that can create overvoltage transients at high frequencies (i.e., higher than the system frequency). These overvoltage signals can be quite large (i.e., ten times the system voltage or more) and are superimposed onto the system voltage signal (voltage) such that they can occur or be centered at different phase angles of the system voltage signal. Some causes of these disturbances could include lightning, solar activity, switching within the electrical system, sudden load changes, and the like.

Before proceeding, it is important to note that terms such as “overvoltage”, “overvoltage transient”, “transient overvoltage”, and the like refer to events or signals for which the voltage is greater than what would be expected of the system voltage signal 104 at that particular instant. An overvoltage event can include a voltage transient that does not exceed the maximum voltage of the system voltage signal 104 if that transient event occurs during a low-voltage portion of the system voltage signal 104. It is also important to note that, in general transient events have a higher frequency than the system frequency.

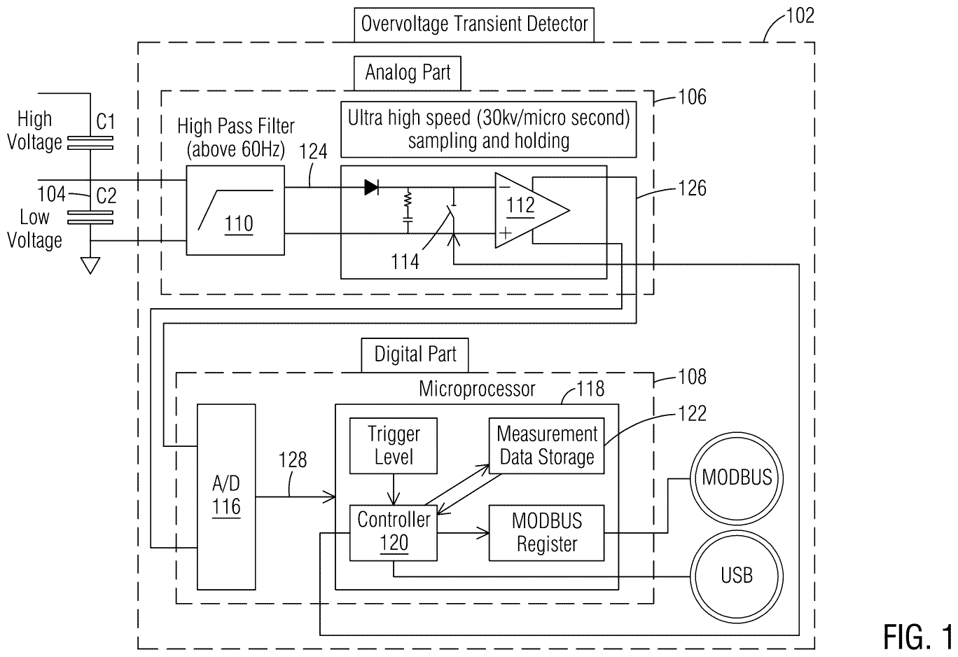

FIG. 1 illustrates a detection system 102 that is connected to a system or device to receive a system voltage signal 104 (i.e., a system transient voltage signal) that is then monitored for transient overvoltage events. Generally, the system voltage signal 104 has a system voltage and a system frequency (e.g., 60 Hz), with any transient overvoltage event having a higher voltage and a higher frequency as compared to the system voltage and the system frequency. The system could include an input side or an output side of a transformer, a generator, a high voltage transmission line, a low voltage transmission line, or any other electrical device or system that may be susceptible to transient voltages.

The detection system 102 includes an analog circuit 106 and a digital circuit 108 that cooperate to detect and analyze the transient overvoltage events. The analog circuit 106 includes a high pass filter 110, an analog amplifier 112 to increase the input impedance, and a switch 114 that operate to hold the transient analog signals produced during the transient overvoltage events that are then passed to the digital circuit 108 for analysis and storage. The high pass filter 110 receives the analog system voltage signal 104 (e.g., a system voltage) and filters out any portion of the system voltage signal 104 below a predetermined frequency. In most constructions, the high pass filter 110 is arranged to filter out any portion of the system voltage signal 104 that falls at or below the system frequency (e.g., 60 Hz). Thus, the high pass filter 110 only passes high-frequency signals as a filtered signal 124 to the remainder of the analog circuit 106. If should be noted that the term “high frequency” as used herein refers to any frequency greater than the system frequency. Thus, in an example system that operates at a system frequency of 60 Hz, any signal greater than 60 Hz would be considered a high frequency signal.

The filtered signal 124 is a transient voltage signal that is delivered to the analog amplifier 112 with a high input impedance for sample hold operation. Thus, operation of the analog amplifier 112 produces and outputs a held analog signal 126 that is delivered to the digital circuit 108.

The switch 114 is a normally open switch that when closed short-circuits analog hold signal 124 and operates to “reset” the analog circuit 106 to allow the analog circuit 106 to detect another transient overvoltage event.

The digital circuit 108 includes an analog to digital convertor 116 and a microprocessor 118 or other computer system that receives and analyzes the held analog signal 126 provided by the analog circuit 106. The analog to digital convertor 116 receives the held analog signal 126 and digitizes that signal to produce an output that includes a digital transient voltage signal 128. The microprocessor 118 analyzes the digital transient voltage signal 128 to determine the level of overvoltage and the number of times that similar overvoltage events have occurred. This data can be stored in a data storage device 122 and/or may be output to a monitor or other output device for display to a user. The microprocessor 118 also includes a controller 120 or performs the function of the controller 120 to signal the switch 114 to close to reset the analog circuit 106 for the detection of another event. Thus, each time the microprocessor 118 records, documents, displays or otherwise determines that an event has occurred and has been measured, the controller 120 resets the analog circuit 106 to detect the next event. The reset process should be very fast (e.g., 10 ms or less) to reduce the likelihood that events in rapid succession are somehow missed.

With continued reference to FIG. 1, it should be noted that the microprocessor 118 or other computer device may output data using other output mechanisms including MODBUS, USB, wireless or cellular transmission, wired output, and the like.

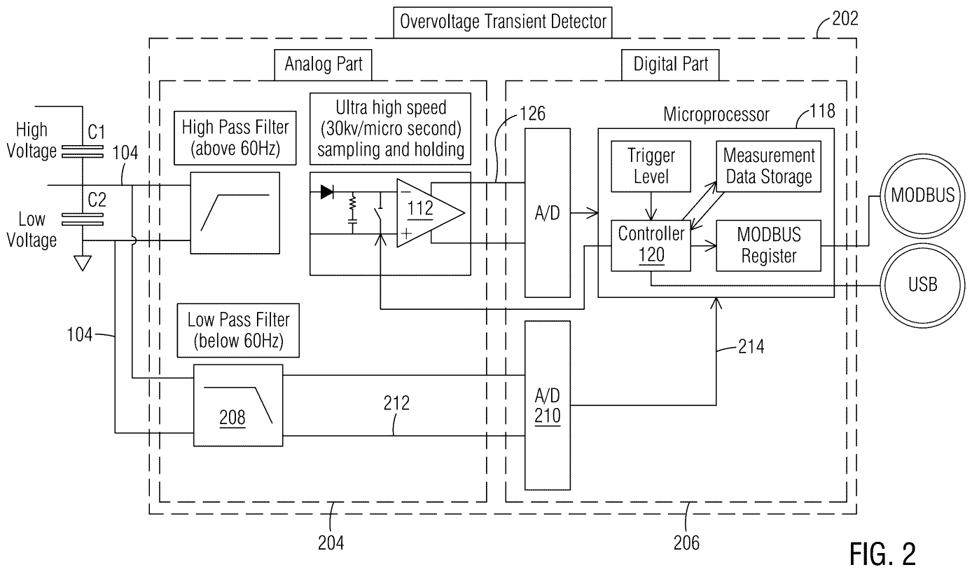

FIG. 2 illustrates an alternative detection system 202 that includes an analog circuit 204 that receives the system voltage signal 104, processes the signal as described with regard to FIG. 1, and then outputs the held analog signal 126. The detection system 202 also includes a digital circuit 206 that receives the held analog signal 126 and performs the analysis and storage process described with regard to FIG. 1.

The analog circuit 204 of the detection system 202 of FIG. 2 also includes a low pass filter 208 that receives the system voltage signal 104 from the system. The low pass filter 208 is arranged to pass only signals having a frequency below a predefined threshold. In this arrangement, the threshold frequency is selected to allow for the passage of the system frequency. For example, if the system operates at a frequency of 60 Hz, the low pass filter 208 would be selected to filter any frequencies greater than 60 Hz, thereby allowing a filtered system voltage signal 212 to pass through the low pass filter 208.

The digital circuit 206 of the detection system 202 of FIG. 2 also includes a second analog to digital convertor 210 that receives the filtered system voltage signal 212 and converts it to a digital system voltage signal 214. The digital system voltage signal 214 is then delivered to the microprocessor 118 or other computer device for use. Specifically, the microprocessor 118 may use the digital system voltage signal 214 to determine the time or location on the system voltage signal 104 at which the detected transient event occurred. Thus, one could detect the level of overvoltage, the quantity of similar events, and the time (or phase angle) during the system voltage signal 104 at which these events occur.

It should be noted that other constructions may eliminate the high pass filter 110 or may include a switch (not shown) that disables the high pass filter 110. In constructions that include the switch, the switch is positioned in one of two positions. In a first position, the high pass filter 110 is connected as illustrated in FIG. 1 and FIG. 2. In a second position, the switch connects a bypass path that allows the system voltage signal 104 to completely bypass the high pass filter 110. Without the high pass filter 110, the system is arranged to detect voltage greater than a predetermined value. While any value can be selected, the predetermined value should be greater than the maximum system voltage. A system that bypasses or does not include the high pass filter 110 will still detect many overvoltage events. however, it will not detect an overvoltage event that occurs at a point in the cycle where the system voltage is low, and the overvoltage is less than the maximum system voltage.

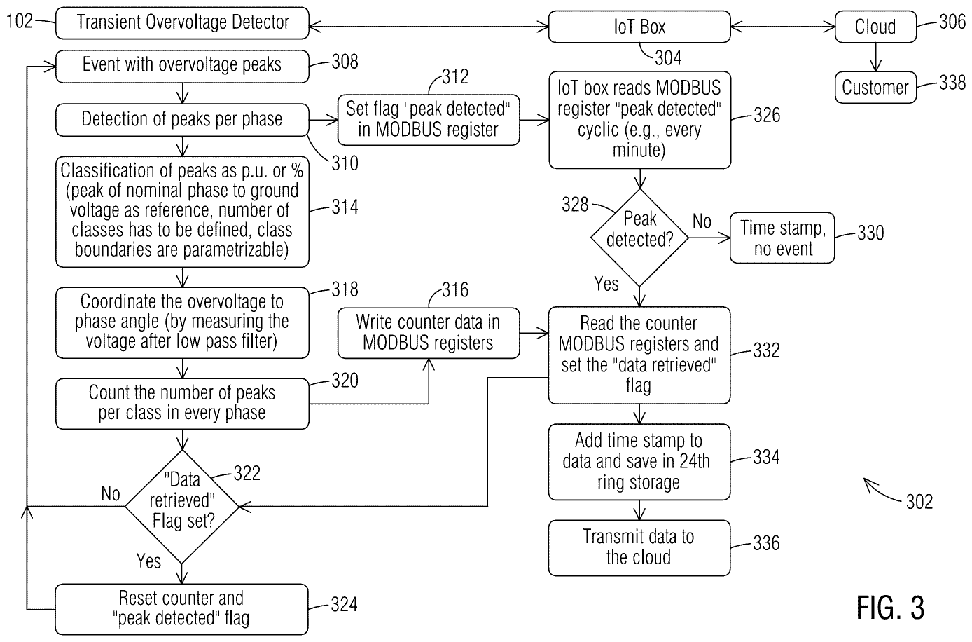

FIG. 3 includes a flow chart that illustrates the overall operation of an overvoltage monitoring system 302 that includes the detection system 102 of FIG. 1, an IoT system 304, and a cloud 306 or other data storage system that may be accessible by users, customers 338, and the like.

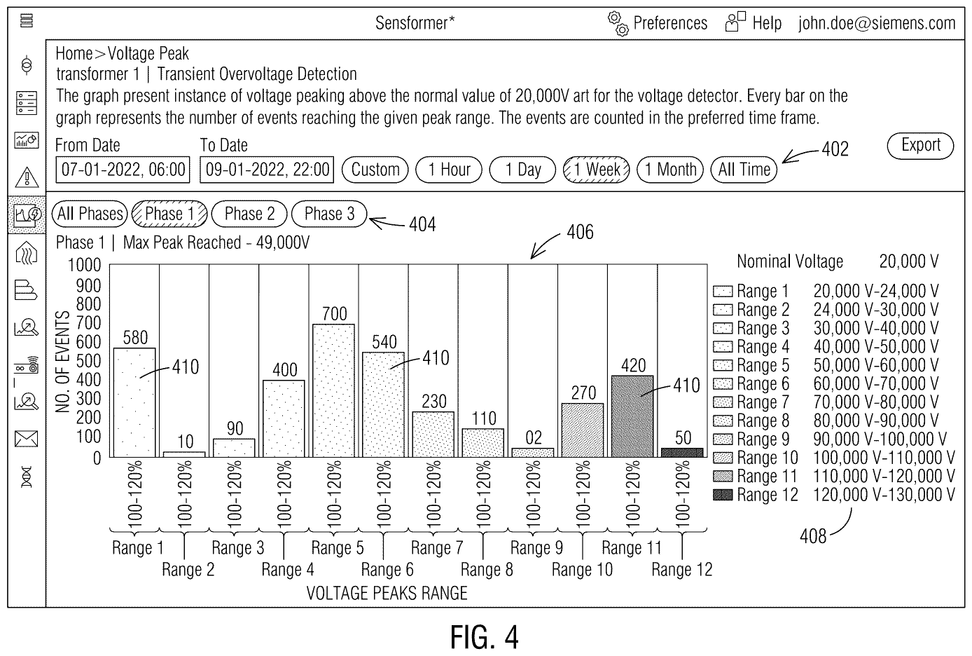

The process initiates following an event detection 308. The data related to the detected event is analyzed to determine the number of peaks per phase 310 and a step is executed to set a MODBUS flag 312 that is indicative of the event being detected. The peak data next passes through a classification step 314 where the data is classified by its magnitude. In some constructions, the peak is classified by its actual voltage while other constructions may classify the voltage relative to the system voltage (e.g., 200% of the system voltage). In most systems, the peaks are classified into groups or ranges. For example, one construction (illustrated in FIG. 4) classifies the peaks in ranges that are percentages of the system voltage. In FIG. 4 the ranges extend from 100% to 650% in increments of 20%, 30%, and 50%. Of course, other ranges and increments are possible as may be required or desired.

With continued reference to FIG. 3, following the classification step 314 some systems may perform a phase angle determination step 318 in which the actual phase angle of the system voltage signal 104 at the time the voltage peak is detected is determined. This additional data can be used to detect patterns between the phase angle of the system voltage signal 104 and overvoltage events as is illustrated in FIG. 6.

Following the classification step 314 or the phase angle determination step 318 in systems that include that step, the data passes through a count step 320 in which the number of peaks in each classification for the event are counted. The count data is passed to a MODBUS register as part of a store count step 316 to assure that the data is stored. Upon the receipt of confirmation that the data has been properly stored, a data retrieve flag 322 is set to allow a reset step 324 to reset the peak detection flag that was set in step 312.

The IoT system 304 functions as an interface between the detection system 102 and the cloud 306 or other data storage system associated with the overvoltage monitoring system 302. The IoT system 304 reads the peak detected flag from the MODBUS at step 326 and checks at step 328 if a time stamp was included. If no time stamp exits, the event is ignored as indicated at step 330. If there is a time stamp, the IoT system 304 reads the MODBUS register to retrieve data from the store count step 316 and switches the data retrieve flag 322 to “yes” to allow for the resetting of the detection system 102. The data is then stored in a storage step 334. The data could be stored in a long-term storage system or may be stored in short term storage that is retrieved and moved periodically. For example, the data could be stored in a 24-hour cycle with data moved daily. Finally, the data is transmitted in a transmission step 336 to the cloud 306 or other storage system.

FIG. 4 is an example of one possible display scheme for the data collected by the detection system 102 and the overvoltage monitoring system 302. The display includes a histogram 406 that is divided into a number of classes 410 with each class 410 representing one overvoltage range. In the illustrated example, the first class 410 includes a count of overvoltage events between 100% and 120% of the system voltage. The second class 410 includes a count of overvoltage events between 120% and 150% of the system voltage. The remaining classes 410 include a count of overvoltage events in ranges that span 50% of the system voltage and extend between 150% and 650% of the system voltage. The class ranges 408 are provided on the right to give the user an indication of the actual voltage values for the various classes 410.

To enhance the histogram 406 a time filter 402 and a phase filter 404 are provided. The time filter 402 allows the user to select one of several predefined time windows for which data will be presented and includes a custom selection that allows for the user to select a custom date or time range. The phase filter 404 allows the user to look at data for any one of the available phases of the system voltage signal 104 (if it is a multiphase signal) or to look at all the phases together.

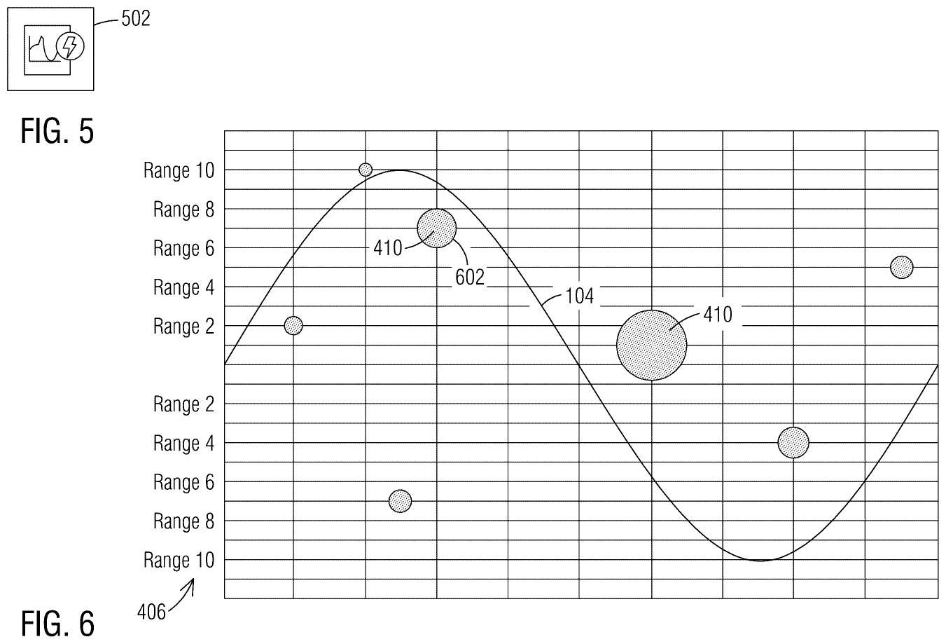

The display scheme of FIG. 4 includes a number of displays with various icons available to select the histogram 406 illustrated in FIG. 4. FIG. 5 illustrates an overvoltage icon 502 that may be used in this listing of icons to lead a user to the desired histogram 406.

FIG. 6 illustrates another possible display that can be produced when using the detection system 202 of FIG. 2. This detection system 202 detects events that include voltage spikes and also detects when they occur with respect to the system voltage signal 104. The display of FIG. 6 includes a Y-axis that is divided into the various class ranges 408. The X-axis represents the phase angle of the system voltage signal 104 plotted against a second Y-Axis. The various circular elements each represent classes 410 of overvoltage spikes with the size of the circle representing the quantity of events in that range and at the particular phase angle of the system voltage signal 104. Thus, a first of the circles 602 represents a number of spikes in Range 7 and occurring between Pi/2 and Pi with respect to the system voltage signal 104.

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, act, or function is an essential element, which must be included in the claim scope: the scope of patented subject matter is defined only by the allowed claims. Moreover, none of these claims are intended to invoke a means plus function claim construction unless the exact words “means for” are followed by a participle.

What is claimed is:

1. A detection system for detecting a transient overvoltage event in an electrical system that operates at a system frequency, the detection system comprising:
an analog circuit connected to the electrical system and including a high pass filter operable to allow for the passage of a transient voltage signal having a signal frequency greater than the system frequency;
a digital circuit including an analog to digital convertor that operates to convert the transient voltage signal to a digital transient voltage signal and a microprocessor operable to receive the digital transient voltage signal, to direct the digital transient voltage signal to a data storage device for storage in an overvoltage database, and to reset the analog circuit; and
a computer system operable to output the data stored in the overvoltage database.

2. The detection system of claim 1, wherein the analog circuit further comprises an analog amplifier that receives the transient voltage signal and holds the transient voltage signal for a time period that exceeds a time duration of the transient overvoltage event.

3. The detection system of claim 1, further comprising a switch arranged to produce a short circuit in the analog circuit to reset the analog circuit, the switch movable by the microprocessor between an open position and a closed position.

4. The detection system of claim 1, further comprising a low pass filter operable to allow for the passage of a system voltage signal at the system frequency.

5. The detection system of claim 4, further comprising a second analog to digital convertor operable to convert the system voltage signal to a digital system voltage signal.

6. The detection system of claim 5, wherein the microprocessor receives the digital system voltage signal to determine a phase angle of the system voltage signal at the time of the generation of the transient voltage signal.

7. The detection system of claim 1, wherein the electrical system is a three-phase electrical system and wherein the analog circuit and the digital circuit are connected to a first phase of the electrical system and wherein the detection system further comprises a second analog circuit and a second digital circuit connected to a second phase and a third analog circuit and a third digital circuit connected to a third phase.

8. A detection system for detecting a transient overvoltage event in an electrical system that operates at a system frequency, the detection system comprising:
an analog circuit connected to the electrical system and including:
a high pass filter operable to allow for the passage of a transient voltage signal having a signal frequency greater than the system frequency; and
a low pass filter operable to allow for the passage of a system voltage signal at the system frequency;
a digital circuit including:
an analog to digital convertor that operates to convert the transient voltage signal to a digital transient voltage signal and to convert the system voltage signal to a digital system voltage signal; and
a microprocessor operable to receive the digital transient voltage signal and the digital system voltage signal and to compare the digital transient voltage signal and the digital system voltage signal to determine a phase angle of the system voltage signal when the transient voltage signal was generated, the microprocessor further operable to determine an overvoltage value, to direct the overvoltage value and the associated phase angle to a data storage device for storage in an overvoltage database, and to reset the analog circuit; and
a computer system operable to output the data stored in the overvoltage database.

9. The detection system of claim 8, wherein the analog circuit further comprises an analog amplifier that receives the transient voltage signal and holds the transient voltage signal for a time period that exceeds a time duration of the transient overvoltage event.

10. The detection system of claim 8, further comprising a switch arranged to produce a short circuit in the analog circuit to reset the analog circuit, the switch movable by the microprocessor between an open position and a closed position.

11. The detection system of claim 8, further comprising a second analog to digital convertor operable to convert the system voltage signal to the digital system voltage signal.

12. The detection system of claim 8, wherein the electrical system is a three-phase electrical system and wherein the analog circuit and the digital circuit are connected to a first phase of the electrical system and wherein the detection system further comprises a second analog circuit and a second digital circuit connected to a second phase and a third analog circuit and a third digital circuit connected to a third phase.

13. A method of detecting a transient overvoltage event in an electrical system that operates at a system frequency, the method comprising:
passing a signal from the electrical system to an analog circuit;
filtering the signal to pass a first transient voltage signal having a signal frequency greater than the system frequency;
amplifying the first transient voltage signal;
converting the first transient voltage signal to a digital transient voltage signal in a digital circuit;
determining an overvoltage value for the digital transient voltage signal;
storing the overvoltage value for the digital transient voltage signal; and
resetting the analog circuit to allow the analog circuit to detect a second transient voltage signal.

14. The method of claim 13, further comprising filtering the signal to generate a system voltage signal having the system frequency and converting the system voltage signal to a digital system voltage signal.

15. The method of claim 14, further comprising determining a phase angle of the system voltage signal at the time the transient voltage signal is generated.

16. The method of claim 13, wherein the resetting step includes moving a switch between an open position and a closed position.
